(19) United States
(12) Patent Application Publication
(10) Pub. No.: US 2006/0172515 A1
(43) Pub. Date: Aug. 3, 2006

(54) Method of fabricating a structure in a material

(76) Inventors: Paolo Olivero, Parkville (AU); Sergey Rubanov, Parkville (AU); Patrick Reichart, Parkville (AU); Brant C. Gibson, Parkville (AU); Shane T. Huntington, Sydenham (AU); James Rabeau, Wallie Glen (AU); Andrew D. Greentree, Coburg (AU); Joseph Salzman, Holle (IL); David N. Jamieson, Parkville (AU); Steven Prawer, Caulfield (AU); David F. Moore, Cambridge (GB); Christinia T. Barry, Cambridge (GB)

Correspondence Address: GANZ LAW, P.C., P O BOX 2200, HILLSBORO, OR, 97123, US

(21) Appl. No.: 11/233,545

(22) Filed: Sep. 23, 2005

(30) Foreign Application Priority Data
Jan. 31, 2005 (AU) 2005900385

(51) Int. Cl. H01L 31/0312; H01L 21/425

(52) U.S. Cl. 438/515; 257/77

(57) ABSTRACT

A method of fabricating a structure in a material.

### CROSS REFERENCE TO RELATED APPLICATIONS

This application claims priority to and the benefit of Australian patent application number 2005900385, filed on Jan. 31, 2005, the entire disclosure of which is hereby incorporated by reference as if set forth in its entirety for all purposes.

### FIELD OF THE INVENTION

The present invention broadly relates to a method of fabricating a structure in a material. The present invention relates particularly, though not exclusively, to a method of fabricating a structure in a single crystalline material, such as in single-crystalline diamond.

### BACKGROUND OF THE INVENTION

Micro-machined devices often comprise three dimensional components that may overhang other components. The performance of many optical and mechanical micro-machined devices may be improved if the three-dimensional components have materials properties such as those of diamond. In particular single crystalline diamond is very hard, is chemically inert and has a high optical refractive index.

Polycrystalline films comprising small diamond crystallites are, for example, grown using chemical vapour deposition. Such films do not have all of the advantageous properties of single crystalline diamond, but are nevertheless useful. Fabricating three-dimensional micro-structures that are composed of such diamond material is, however, still a challenge and is particularly difficult if the micro-structure should be composed of single crystalline diamond.

### SUMMARY OF THE INVENTION

The present invention provides in a first aspect a method of fabricating a structure in a diamond material or diamond like carbon material, the material having first, second and third regions, the first region including a surface of the material and the second region being positioned below the first region and sandwiched between the first and the third region, the method comprising the steps of:

imposing a structural transformation on a crystallographic structure of the material in the second region, and thereafter

removing at least a portion of the material of the second region.

In one specific embodiment of the present invention the first region is composed of single-crystalline diamond. The step of removing at least a portion of the second region may be performed so that a portion of the first region is undercut and a three-dimensional structure is fabricated having the advantageous materials properties of single crystalline diamond which is a significant advantage for device performance.

The material may be provided with the first, second and third regions being composed of single crystalline diamond.

In one embodiment of the present invention the first region may be referred to as cap region, the second region may be referred to as sacrificial region and the third region may be referred to as substrate region.

The step of imposing a structural transformation on the crystallographic structure typically comprises damaging the crystallographic structure. In a specific embodiment of the present invention this comprises bombardment with ions. It is known that high energy ions, such as ions having an energy above 1 MeV, damage the crystallographic structure predominantly at a depth of one or more micrometers below the surface. Ions having a lower energy damage the crystallographic structure closer to the surface. For example, He ions having an energy of approximately 100 keV damage the crystallographic structure predominantly at a depth of about 300 nm, but heavier ions will damage closer to the surface. In addition the ion type and dose also influences the depth and thickness of a layer in which the crystallographic structure is predominantly damaged.

The method comprises in a specific embodiment the step of controlling a depth and/or a thickness of a region in which the crystallographic structure is predominantly damaged by controlling an ion bombardment energy. For example, the ion bombardment may comprise ions having a broad range of energies and the thickness of the region in which the crystallographic structure is predominantly damaged would then be relatively thick. Alternatively or additionally, the ion bombardment may comprise more than one ion bombardment procedures conducted at different ion energies. The ions typically are directed to the surface of the material.

The thickness of the first region and/or the ion beam energy typically are selected so that the ions predominantly damage the crystallographic structure in the second region.

The method may also include the additional step of annealing the material after damaging the crystallographic structure in the second region. The ion bombardment and annealing conditions may be selected so that graphite is formed in the second region, whereas any damage in the first region typically is removed.

The method may comprise the step of forming a conduit for a fluid through a portion of the first region to the second region using a focussed ion or electron beam or a laser. In a specific embodiment this step comprises patterning the surface by cutting through the first region in a manner such that an island of material of the first region is formed on the second region.

The step of removing the material of the second region may comprise etching such as chemical etching, electrochemical etching, plasma etching or exposing the sample to hot gases such as hot oxygen. In this case an etch fluid, such as an etch liquid, may be directed through the conduit to the second region and selected so that material of the second region is removed by etching and at least a portion of the first region is undercut. If the or each island of the first region is entirely undercut, the or each island typically is lifted off. Alternatively or additionally, at least one portion of the first region may be at least partially undercut so that a cavity is formed between the first and the third region and a portion of the first region overhangs the third region.

In a specific example the material of the first and third regions comprises diamond and the second region comprises graphite formed after ion bombardment and after annealing. The graphite may be removed using, for example, a wet-chemical etch process that selectively etches graphite and has a lower etch rate for diamond. (the etch rate for the diamond is almost zero by comparison)

The method may comprise a further annealing step after the material of the second region has been removed. This annealing step may be conducted at a relatively high temperature, such as a temperature of more than 1000° C., which reduces damages that the ion bombardment may have caused in the first region

For example, the method may be used to form bridges or cantilever structures of a portion of the first region which overhang the third region.

The present invention provides in a second aspect a structure fabricated by the method according to the first aspect of the present invention.

The present invention provides in a third aspect a high frequency resonator, comprising:

a body portion and

a resonator portion that in use resonates at the high frequency, the resonator portion overhanging a region of the body portion,

wherein the body portion and the resonator are formed from single crystalline diamond.

As diamond is a very hard material, the resonator according to the third aspect of the present invention has the advantage of having a high resonance frequency if sufficiently small proportioned.

The body portion and the resonator may be integrally formed from one diamond single crystal.

The resonator portion may be a cantilever portion.

The resonator portion of the high frequency resonator typically is fabricated using the method according to the first aspect of the present invention.

The present invention provides in a fourth aspect an optical device comprising:

a body portion and

a waveguide, the waveguide overhanging a region of the body portion,

wherein the body portion and the waveguide are formed from single crystalline diamond.

For example, the waveguide may be elongated and may comprise an end surface that may be arranged to function as a mirror and to divert light by total internal reflection.

The body portion and the waveguide may be integrally formed from one diamond single crystal.

The waveguide may also comprise a photon source such as any type of colour centre including those having at least one optically active impurity atom.

In another specific embodiment of the present invention, the optical device comprises a conduit for a fluid positioned in the proximity of the waveguide and arranged so that in use the guided light will be influenced by a refractive index of the liquid. As the influence of the liquid on the optical properties depends on the refractive index of the liquid, the optical device may be used as a sensor for the liquid and the guided light may be analysed to identify the liquid. The optical device according to this embodiment has the particular advantage that the liquid can be reactive as diamond has a high chemical inertness. Further, because of the advantageous mechanical and high temperature properties diamond, the optical device is also suitable for high temperature and high pressure applications.

The optical device typically is fabricated using the method according to the first aspect of the present invention.

The invention will be more fully understood from the following description of specific embodiments of the invention. The description is provided with reference to the accompanying drawings.

### BRIEF DESCRIPTION OF THE DRAWINGS

FIG. 1 shows an optical microscopy image of a material having ion bombarded regions according to a specific embodiment of the present invention,

FIG. 2 shows a calculated plot of vacancy density versus depth for the ion bombardment,

FIG. 3 shows a schematic diagram of patterned features according to a specific embodiment of the present invention,

FIG. 4 shows a scanning electron microscopy micrograph of a patterned structure according to a specific embodiment of the present invention,

FIG. 5 shows optical microscopy images of the structure shown in FIG. 4 after exposure to wet chemical etching,

FIG. 6 shows a scanning electron microscopy micrograph of a cantilever structure according to a specific embodiment of the present invention,

FIG. 7 shows a scanning electron microscopy micrograph of a bridge structure according to a specific embodiment of the present invention,

FIG. 8 shows (a) a schematic top view and (b) a schematic cross-sectional view of a structure according to an embodiment of the present invention, and

FIG. 9 shows schematic perspective and side views of a structure according to an embodiment of the present invention.

### DETAILED DESCRIPTION OF SPECIFIC EMBODIMENTS

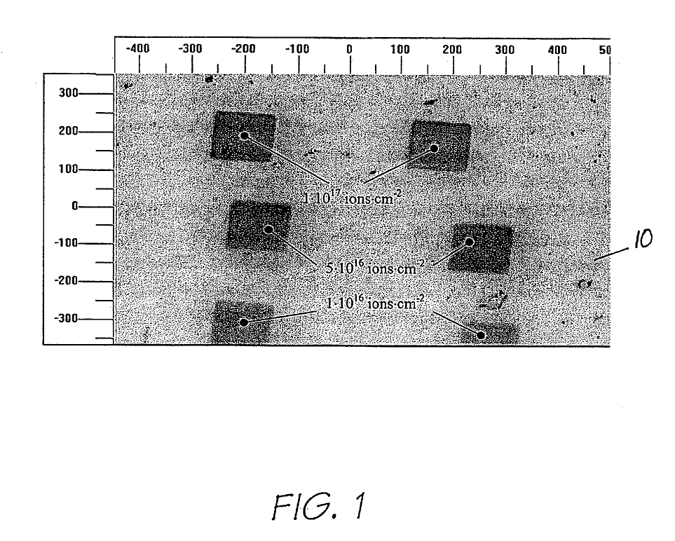

Referring initially to FIGS. 1 to 6, a method of fabricating a structure in a material according to a specific embodiment of the present invention is now described.

FIG. 1 shows an optical microscopy image of a diamond material 10. In this embodiment, the diamond material is single crystalline. The diamond may be a naturally grown or may be synthetically fabricated. The image shows six areas on the material 10 which are bombarded with high energy ions. In this embodiment, an ion beam having an energy of 2 MeV was used to bombard the six surface regions and the total flux was 10¹⁶ to 10¹⁷ ions per cm². Each ion bombardment area has a size of approximately 100×100 μm².

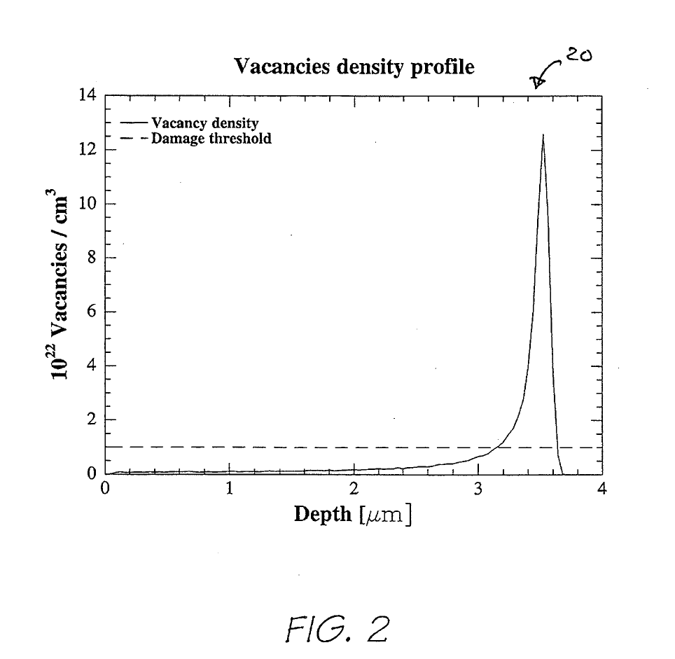

FIG. 2 shows a plot 20 indicating the damage that has been caused by the ion bombardment as a function of depth below the surface of the material 10. The plot 20 shows data which was obtained using a Monte Carlo simulation. As can be seen from the plot 20, a surface layer having a thickness of approximately 3 μm is largely undamaged and the damage is concentrated to a depth between 3 and 4 μm. It is known that above a threshold of approximately 10²² vacancies per cm³, diamond is predominantly converted into graphite if subsequently annealed. A subsequent annealing process at 550° C. for approximately one hour in air therefore formed a graphite layer at a depth of approximately 3 to 4 μm with the surface layer maintaining largely its diamond structure up to a depth of approximately 3 μm. It will be appreciated, however, that in variations of this embodiment other ion energies may be chosen so as to control the depth and thickness of a layer in which the crystallographic structure is predominantly damaged.

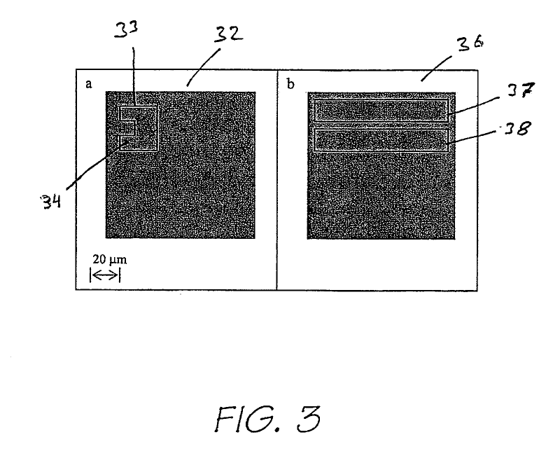

FIG. 3 shows schematically two of the six ion bombarded areas which were shown in FIG. 1. In area 32 a structure 33 was written using a 30 keV focused Gallium ion beam having a beam spot size of approximately 1 μm. The beam was guided so that an island 34 was formed. Further, the beam was selected and the material is cut to a depth of the graphite layer so that the island 34 is a diamond island positioned on the graphite layer formed by the ion bombardment and subsequent annealing as discussed above. The same procedure was performed for area 36 and in this case the focused Gallium ion beam was directed so that two islands, 37 and 38 were formed on the graphite layer. In each case, the Gallium ion beam had an energy of approximately 30 keV with a beam current of approximately 1 to 2 nA, a beam size of approximately 1 μm, and a milling rate of 0.1 μm³/nC.

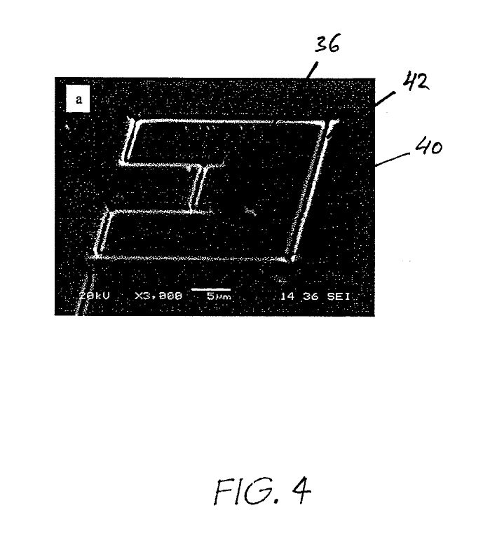

As an example, FIG. 4 shows a secondary electron microscopy micrograph 40 showing the island 34. The channel 42 which was written by the gallium ion beam through the diamond surface layer can clearly be seen in FIG. 4.

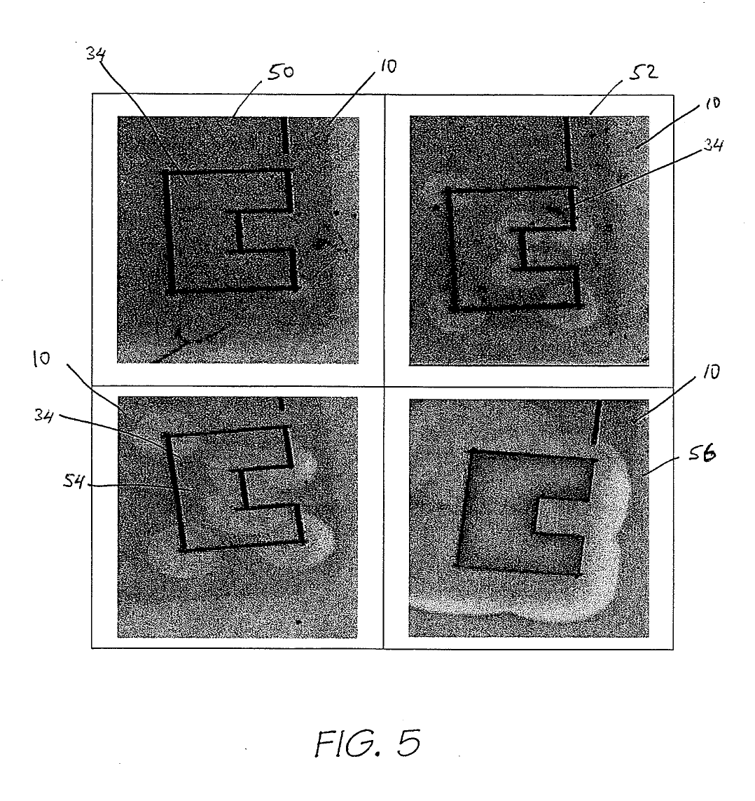

FIG. 5 shows four optical microscopy images 50, 52, 54 and 56. Image 50 was taken after the material 10 was exposed to a boiling acid solution comprising one part H₂SO₄, one part HNO₃ and one part HClO₄. This solution is known to preferentially etch graphite. The light-coloured areas at corners of the island 34 correspond to areas where the graphite layer has been etched away. Images 52 and 54 show the material 10 with the island 34 after longer exposure to the boiling acid solution. Eventually the graphite layer underneath island 36 is been etched away and, since the island 34 is then no longer connected with the material 10, the island 34 is been lifted off the material 10. Image 56 shows the material 10 without the island 36.

After this wet etching process the material 10 is annealed in forming gas (4% hydrogen in argon) at a temperature of approximately 1100° C. for approximately two hours. This annealing process heals the remaining defects that may have been formed in the diamond material when the material 10 was exposed to bombardment by the high energy ions.

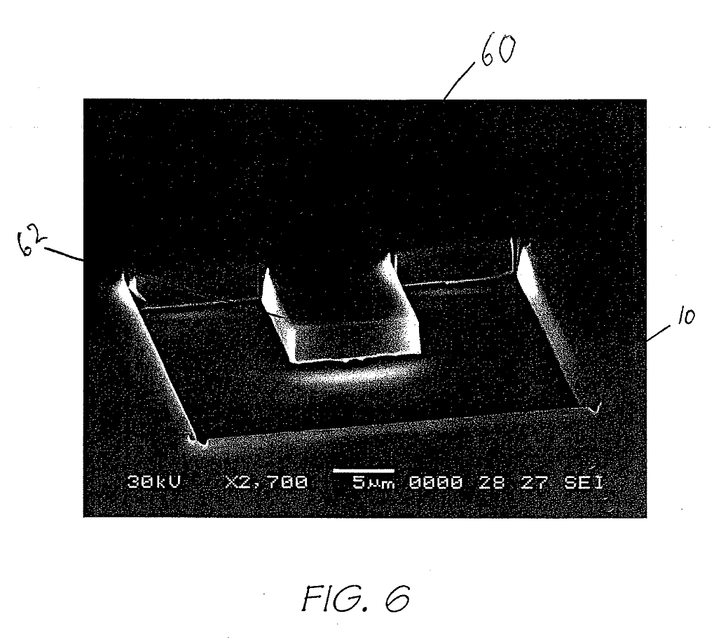

FIG. 6 shows a secondary electron microscopy micrograph of the structure that was formed by the above described method and that is also shown in image 56. The micrograph 60 shows a substantially U-shaped cavity carved into the diamond material of the material 10. The wet etching process removed the graphite layer that was positioned underneath tongue 62 and tongue 62 therefore is a cantilever structure overhanging a portion of the material 10.

This particular structure has the significant advantage that the tongue 62 maintains all advantageous properties of a single crystalline diamond. For example, single crystalline diamond is very hard and has a very high Young's modulus. Consequently, a resonance frequency of the tongue 62 is very high and the structure shown in FIG. 6 may be used as a high frequency resonator in which the tongue 62 is resonating at the high frequency. For example, this may be effected by applying a thin film metallic electrode to the tongue 62 and subjecting the electrode to an alternating electrical field.

It will be appreciated, however, that the structure shown in FIG. 6 is only one example of a possible structure that may be formed by the process described above.

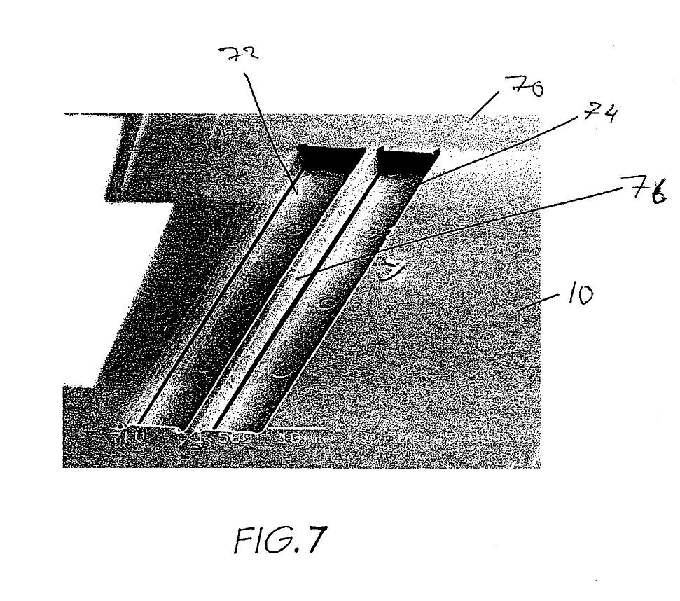

FIG. 7 shows a secondary electron microscopy micrograph 70 of another structure that was formed by the above-described method. In this embodiment, two elongated regions 72 and 74 were carved into the material 10 and a bridge portion 76 was formed between the elongated portions. As the bridge portion 76 was positioned on a graphite layer which was etched away by the wet etching process in the method as described above, the bridge portion 76 is overhanging a portion of this material 10. Such a free-hanging bridge structure may, for example, be used as an optical waveguide having the advantageous optical properties of single crystalline diamonds, such as high refractive index and very low optical scattering losses.

In a variation of the embodiment shown in FIG. 7 the shown structure is used as a fluid sensor. In this embodiment, a fluid is directed in a conduit adjacent the bridge portion 76. For example, the fluid may be directed in the elongated channel portions 72 and 74. In this embodiment, the bridge portion 76 has a diameter of the order of 2 μm and light guided in the bridge portion will experience a change in light guiding properties if a refractive index of a medium adjacent the bridge portion 76 changes. Consequently, the light guiding properties of the bridge portion 76 depend on a refractive index of a fluid guided in portions 72 and 74. Therefore, analysis of the guided light makes it possible to characterise, and typically identify, the fluid guided in the portions 72 and 74. As diamond has a high corrosion resistance, fluids that may be detected may also be corrosive, which is of significant practical advantage.

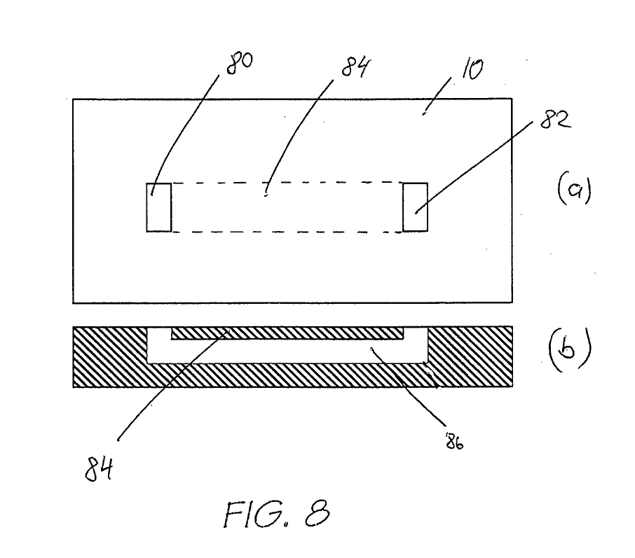

FIG. 8 shows in a further variation of this embodiment another device structure which may be used to detect a fluid. A fluid inlet 80 and a fluid outlet 82 were formed in the substrate 10 in a same manner as channel portions 72 and 74 were formed. In the embodiment shown in FIG. 8, however, a bridge portion 84 is formed so that an elongate channel 86 is provided covered by the bridge portion 84. The channel 86 connects the inlet 80 with the outlet 82 and in use a fluid is directed through the channel 86. The bridge portion 84 was formed in the same manner as the bridge portion 76. In use, light is guided in the bridge portion 84 to detect the fluid in the fluid in the channel 86.

It is to be appreciated that alternatively the fluid inlet and outlet openings may be positioned at the under side of the substrate 10 or at side portions of the substrate 10.

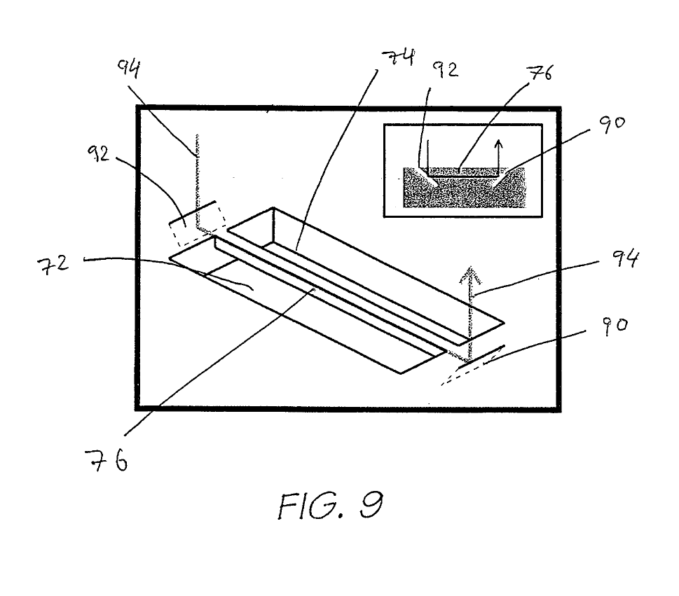

FIG. 9 shows another variation of the embodiment shown in FIG. 7. FIG. 9 shows the bridge structure 76 and void portion 90 and 92 were carved using a gallium ion beam for ion milling. In order to remove damage from ion milling at surfaces of the void portions 90 and 92, the structure was annealed at 1100° C., and formed graphite was then etched away using the above described method.

In this embodiment the void areas 90 and 92 are planar and positioned at end portions of the bridge portion 76. The void areas are positioned at an angle of 45° and 135° relative to a top surface of the device and function as mirrors. At the interface of the void areas with the diamond materials (surfaces angled at 45° and 135° degrees) light guided in the bridge portion 76 is reflected by total internal reflection in a manner as indicated by arrow 94 and the formed mirrors can therefore be used to direct light into and out of the bridge portion 76.

In the embodiment shown in FIG. 9 the bridge portion has a cross-sectional dimension of approximately 2 mm×3.4 mm but it is to be appreciated that in variations of this embodiment the bridge portion 76 may have other dimension. The light guiding properties of the device shown in FIG. 9 and described above have been tested and it has been demonstrated that light is guided by the device. The device according to this embodiment is suitable for multi-mode propagation of the guided light. In variations of this embodiment the device may also be designed for single mode propagation of the guided light.

The bridge portion 76 may also comprise a photon source such as colour centre having at least one optically active impurity atom which is positioned adjacent to a vacancy in the diamond matrix.

Although the invention has been described with reference to particular examples, it will be appreciated by those skilled in the art that the invention may be embodied in many other forms. For example, materials other than diamond, especially diamond-like carbon, polycrystalline diamond and tetrahedral amorphous carbon, may be used for fabricating structures according to the described embodiments. Further, the described structures are only examples of a range of structures that may be formed. Alternative structures that may be formed include for example beam-splitters. For example, formed free-hanging structures may be curved or may have any other geometric shape.

A person skilled in the art will also appreciate that other ion bombardment, annealing and chemical etching conditions may be used to for specific fabricate structures. For example more complicated structures may be formed using a sequence of ion implantation, annealing and etching steps. Further, ion bombardment may comprise separate steps in which a diamond surface is bombarded at different energies so as to create damaged layers at different depths.

What is claimed is:

1. A method of fabricating a structure in a diamond material or diamond like carbon material, the material having first, second and third regions, the first region including a surface of the material and the second region being positioned below the first region and sandwiched between the first and the third region, the method comprising:
imposing a structural transformation on a crystallographic structure of the material in the second region, and thereafter
removing at least a portion of the material of the second region.

2. The method as claimed in claim 1 wherein the first region is composed of single-crystalline diamond.

3. The method as claimed in claim 1 wherein removing at least a portion of the second region is performed so that a portion of the first region is undercut and a three-dimensional structure is fabricated.

4. The method as claimed in claim 1 wherein the material is provided with the first, second and third regions being composed of single crystalline diamond.

5. The method as claimed in claim 1 wherein imposing a structural transformation on the crystallographic structure comprises damaging the crystallographic structure.

6. The method as claimed in claim 5 wherein damaging the crystallographic structure comprises ion bombardment.

7. The method as claimed in claim 6 comprising controlling a depth and/or a thickness of a region in which the crystallographic structure is predominantly damaged by controlling a kinetic ion bombardment energy.

8. The method as claimed in claim 7 wherein the second region is predominantly damaged by the ion bombardment.

9. The method as claimed in claim 8 comprising annealing the material after damaging the crystallographic structure in the second region.

10. The method as claimed in claim 9 wherein conditions for damaging the second region and annealing are selected so that graphite is formed in the second region.

11. The method as claimed in claim comprising forming a conduit for a fluid through a portion of the first region to the second region.

12. The method as claimed in claim 1 comprising patterning the surface by cutting through the first region in a manner such that an island of material of the first region is formed on the second region.

13. The method as claimed in claim 1 wherein removing the material of the second region comprises at least one of chemical etching, electrochemical etching, plasma etching or exposing the sample to hot gases.

14. The method as claimed in claim 13 wherein an etch fluid is directed through the conduit to the second region and selected so that material of the second region is removed by etching so that at least a portion of the first region is undercut and a cavity is formed between the first and the third region and a portion of the first region overhangs the third region.

15. The method as claimed in claims 11 wherein an etch fluid is directed through the conduit to the second region and selected so that material of the second region is removed by etching so that the island region is undercut lifted off.

16. A structure fabricated by the method as claimed in claim 1.

17. A high frequency resonator, comprising:
a body portion and
a resonator portion that in use resonates at the high frequency, the resonator portion overhanging a region of the body portion,
wherein the body portion and the resonator portion are formed from single crystalline diamond.

18. The high frequency resonator as claimed in claim 17 wherein the body portion and the resonator portion are integrally formed from one diamond single crystal.

19. The high frequency resonator as claimed in claim 17 wherein the resonator portion is a cantilever portion.

20. An optical device comprising:
a body portion and
a waveguide, the waveguide overhanging a region of the body portion,
wherein the body portion and the waveguide are formed from single crystalline diamond.

21. The optical device as claimed in claim 20 wherein the waveguide is elongated and comprises at least one end surface that is arranged to function as a mirror and to divert light by total internal reflection.

22. The optical device as claimed in claim 20 wherein the body portion and the waveguide are integrally formed from one diamond single crystal.

23. The optical device as claimed in claim 20 wherein the waveguide comprises a colour centre.

24. The waveguide as claimed in claim 20 comprising a conduit for a fluid positioned in the proximity of the waveguide and arranged so that in use the guided light will be influenced by a refractive index of the liquid.
